(19) United States
(12) Patent Application Publication
(10) Pub. No.: US 2025/0313698 A1
(43) Pub. Date: Oct. 9, 2025

(54) DUAL-CURED ORGANOSILICON POLYMER-BENZOXAZINE-EPOXY RESIN HYBRID ENCAPSULATION MATERIAL AND PREPARATION METHOD THEREFOR

(71) Applicants: GUANGZHOU BAIYUN TECHNOLOGY CO., LTD., Guangdong (CN); GUANGDONG BAIYUN TECHNOLOGY CO., LTD., Guangdong (CN)

(72) Inventors: Zien FU, Guangdong (CN); Feiliang DAI, Guangdong (CN); Xidu LI, Guangdong (CN); Jinbo JIANG, Guangdong (CN)

(73) Assignees: GUANGZHOU BAIYUN TECHNOLOGY CO., LTD., Guangdong (CN); GUANGDONG BAIYUN TECHNOLOGY CO., LTD., Guangdong (CN)

(21) Appl. No.: 19/246,708

(22) Filed: Jun. 24, 2025

Related U.S. Application Data
(63) Continuation of application No. PCT/CN2022/144063, filed on Dec. 30, 2022.

(51) Int. Cl. C08L 83/04; C08G 77/08; C08K 3/26; C08K 5/5419

(52) U.S. Cl. CPC C08L 83/04; C08G 77/08; C08K 3/26; C08K 5/5419; C08K 2003/265; C08K 2201/011; C08L 2201/08; C08L 2201/14; C08L 2203/206

(57) ABSTRACT

Disclosed in the present invention are an organosilicon polymer-benzoxazine-epoxy resin hybrid encapsulation material and a preparation method therefor. The organosilicon polymer-benzoxazine-epoxy resin hybrid encapsulation material is prepared from raw materials comprising the following components: organosilicon-modified benzoxazine SMB, organosilicon-modified epoxy resin SME, bisphenol A benzoxazine resin, aliphatic epoxy resin, an organosilicon polymer, a catalyst, a crosslinking agent, and a powder filler. The organosilicon-modified benzoxazine SMB is a mixture prepared from a BZ compound, vinyltrimethoxysilane and double-end hydrogen-containing silicone oil by means of a hydrosilylation reaction under the catalysis of a platinum catalyst; and the organosilicon-modified epoxy resin SME is a mixture prepared from an allyl glycidyl ether, vinyltrimethoxysilane and double-end hydrogen-containing silicone oil by means of a hydrosilylation reaction under the catalysis of a platinum catalyst. The encapsulation material has low gas permeability, low internal stress, good flexibility, and excellent cold and hot aging resistance.

### CROSS-REFERENCE TO RELATED APPLICATION

This application is a continuation of international application of PCT patent application PCT/CN2022/144063, filed on Dec. 30, 2022. The entirety of the above-mentioned patent application is hereby incorporated by reference herein and made a part of this specification.

### TECHNICAL FIELD

The present disclosure relates to the field of encapsulation adhesive technology, particularly to a dual-cured organosilicon polymer-benzoxazine-epoxy resin hybrid encapsulation material and preparation method therefor.

### BACKGROUND

The photoelectric effect caused by hole-electron pairs in optoelectronic materials has a wide range of applications in the energy field, such as LED/OLED, solar cells, etc. Optoelectronic devices, as carriers of photoelectric conversion, play a key role in energy conversion efficiency and utilization efficiency. Due to the high sensitivity of optoelectronic materials to water molecules, oxygen molecules, etc. in the air during the photoelectric conversion process, optoelectronic device encapsulation materials have strict requirements for the permeability of molecules such as water vapor and oxygen. For example, the water vapor permeability of OLED encapsulation needs to be very low to meet its long lifespan requirements. Perovskite-based solar cells are also extremely sensitive to gas. Therefore, the requirements for low water vapor permeability encapsulation materials (encapsulation adhesives) in the encapsulation of electronic devices (especially optoelectronic devices) are becoming increasingly stringent.

Epoxy resin and organic silicon polymer are widely used in electronic device encapsulation. Epoxy resin, as a thermosetting rigid material, has excellent electrical properties and low gas permeability. However, due to their rigid nature, they have high internal stress after curing, which limits their application in encapsulation fields with large dimensions and high requirements for thermal cycling. Organic silicon material chains have good flexibility and excellent weather resistance, making them suitable for applications requiring high and low temperature resistance and weather resistance requirements. However, the gas permeability of silicone materials is high, which is the limitation when they are used alone in the field of electronic encapsulation.

### DESCRIPTION OF RELATED ART

Based on the above, the purpose of the present disclosure is to provide a encapsulation material with low gas permeability, low internal stress, good flexibility, and excellent resistance to cold and heat aging after curing.

In order to achieve the above purpose, the present disclosure includes the following technical solutions.

An organosilicon polymer-benzoxazine-epoxy resin encapsulation material, being prepared from raw materials including the following components in parts by weight:

| | | |
|---|---|---|
| organosilicon-modified benzoxazine (SMB) | 10 to 100 | parts |
| organosilicon-modified epoxy resin (SME) | 10 to 100 | parts |
| bisphenol A benzoxazine resin | 10 to 30 | parts |
| aliphatic epoxy resin | 10 to 100 | parts |
| organosilicon polymer | 10 to 150 | parts |
| a catalyst | 0.0001 to 1 | part |
| a crosslinking agent | 0.5 to 10 | parts |
| a powder filler | 10 to 100 | parts |

wherein, the organosilicon-modified benzoxazine is a mixture prepared by a hydrosilylation reaction of a BZ compound, vinyltrimethoxysilane, and a double-end hydrogen-containing silicone oil under the catalysis of a platinum catalyst;
the structural formula of the BZ compound is as follows:

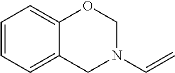

the organosilicon-modified epoxy resin is a mixture prepared by a hydrosilylation reaction of allyl glycidyl ether, vinyltrimethoxysilane, and double-end hydrogen-containing silicone oil under the catalysis of a platinum catalyst.

Preferably, the organosilicon-modified benzoxazine contains a polymer with the following structure:

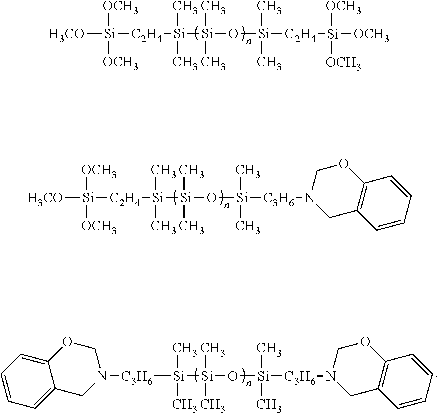

Preferably, the organosilicon-modified epoxy resin contains a polymer with the following structure:

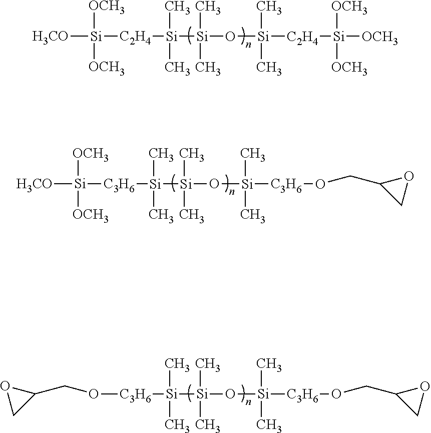

The organosilicon polymer-benzoxazine-epoxy resin hybrid encapsulation material of the present disclosure can be prepared as a bi-component organosilicon polymer-benzoxazine-epoxy resin hybrid encapsulation adhesive by conventional methods, or as a single-component organosilicon polymer-benzoxazine-epoxy resin hybrid encapsulation adhesive.

Wherein, the organosilicon polymer-benzoxazine-epoxy resin hybrid encapsulation material is a bi-component hybrid encapsulation adhesive, and its component A is a mixture of the organosilicon-modified benzoxazine, the organosilicon-modified epoxy resin, the bisphenol A benzoxazine resin, the aliphatic epoxy resin, and the crosslinking agent; its component B is a mixture of the organosilicon polymer, the powder filler, and the catalyst.

The raw materials for preparing the organosilicon polymer-benzoxazine-epoxy resin single-component hybrid encapsulation adhesive further include 5 to 10 parts of silazane.

The present disclosure also provides a method for preparing an organosilicon polymer-benzoxazine-epoxy resin hybrid encapsulation adhesive, which includes the following steps:
adding the organosilicon polymer and the powder filler into a kneading machine, and then adding silazane for modification and refining to obtain a liquid base material;
transferring the liquid base material into a planetary machine, and then sequentially adding the organosilicon modified benzoxazine, the organosilicon modified epoxy resin, the bisphenol A benzoxazine resin, and the aliphatic epoxy resin; heating up to 80° C. to 120° C., mixing evenly, cooling, and then adding the crosslinking agent and the catalyst in an anhydrous environment to obtain the single-component hybrid encapsulation adhesive.

The organosilicon polymer-benzoxazine-epoxy resin hybrid encapsulation material of the present disclosure has the following advantages and beneficial effects:
1. The organosilicon polymer-benzoxazine-epoxy resin hybrid encapsulation material of the present disclosure has the advantages of low gas permeability, low internal stress, and excellent resistance to cold and hot aging.
2. The organosilicon polymer-benzoxazine-epoxy resin hybrid encapsulation material of the present disclosure overcomes the problems of high internal stress and easy cracking due to hot and cold alternation of benzoxazine/epoxy resin after curing in electronic device applications, while also solves the defect of poor gas barrier properties in organic silicon electronic device encapsulation.
3. The organic silicon chain segment of the organosilicon polymer-benzoxazine-epoxy resin hybrid encapsulation material of the present disclosure can be cured by moisture in air at room temperature. At this time, the mechanical strength is low, and any problems can be promptly reworked and corrected. After confirming the correctness, the temperature can be raised to 100° C. to 150° C. At this time, the epoxy and oxazine rings can continue to open for thermal curing and crosslinking polymerization, which further improves the mechanical strength of the colloid. This step-by-step dual-curing method can solve the problem of difficult repair during the encapsulation process.

### DESCRIPTION OF THE EMBODIMENTS

The following will further illustrate the technical solutions of the present disclosure through specific embodiments. Technicians in this field should understand that the described embodiments are only intended to help understanding the present disclosure and should not be considered as specific limitations to the present disclosure.

Unless otherwise defined, all technical and scientific terms used in the present disclosure have the same meaning as those commonly understood by those skilled in the art to which the present disclosure belongs. The terms used in the description of the present disclosure are for the purpose of describing specific embodiments only and are not intended to limit the present disclosure.

The terms “including” and “having” of the present disclosure, as well as any variations thereof, are intended to cover non-exclusive inclusions. For examples, a process, method, device, product, or equipment that includes a series of steps is not limited to the listed steps or modules, but optionally includes steps that are not listed, or alternatively includes other steps inherent to these processes, methods, products, or devices.

The term “multiple” mentioned in the present disclosure refers to two or more. “And/or” describes the relationship of the associated objects, indicating that there can be three types of relationships. For example, A and/or B can represent: the existence of A alone, the coexistence of A and B, and the existence of B alone. The character “/” generally indicates that the associated objects are in an “or” relationship.

In one embodiment of the present disclosure, an organosilicon polymer-benzoxazine-epoxy resin hybrid encapsulation material is provided, which is prepared from raw materials including the following components in parts by weight:

| | | |
|---|---|---|
| organosilicon-modified benzoxazine (SMB) | 10 to 100 | parts |
| organosilicon-modified epoxy resin (SME) | 10 to 100 | parts |
| bisphenol A benzoxazine resin | 10 to 30 | parts |
| aliphatic epoxy resin | 10 to 100 | parts |
| organosilicon polymer | 10 to 150 | parts |
| a catalyst | 0.0001 to 1 | part |
| a crosslinking agent | 0.5 to 10 | parts |
| a powder filler | 10 to 100 | parts |

wherein, the organosilicon-modified benzoxazine is a mixture prepared by a hydrosilylation reaction of a BZ compound, vinyltrimethoxysilane, and a double-end hydrogen-containing silicone oil under the catalysis of a platinum catalyst;
the structural formula of the BZ compound is as follows:

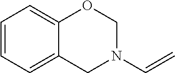

the organosilicon-modified epoxy resin is a mixture prepared by a hydrosilylation reaction of allyl glycidyl ether, vinyl trimethoxysilane, and double-end hydrogen-containing silicone oil under the catalysis of a platinum catalyst.

The present disclosure provides a solution to address the needs for gas barrier, material flexibility, and aging resistance in the field of electronic encapsulation, particularly in the field of optoelectronic encapsulation materials. The technical solution of the present disclosure combines the characteristics of high and low temperature resistance, UV aging resistance, and good material flexibility of organic silicon materials, as well as the low gas permeability and excellent substrate interface adhesion of epoxy/benzoxazine curing systems, to prepare electronic device encapsulation materials with superior performance.

Specifically, the present disclosure uses benzoxazine compounds with double bond structures, vinyltrimethoxysilane, and double-end hydrogen-containing silicone oil as raw materials to prepare a mixture of organosilicon modified benzoxazine (SMB) through hydrosilylation reaction catalyzed by platinum catalyst; and a mixture of organosilicon modified epoxy resin (SME) was prepared by hydrosilylation reaction using allyl glycidyl ether, vinyltrimethoxysilane, and double-end hydrogen-containing silicone oil as raw materials under the catalysis of platinum catalyst; a hybrid encapsulation material with low gas permeability was prepared by combining the prepared SMB and SME with organic silicon polymers, benzoxazines, epoxy resins, and other raw materials. The cured hybrid encapsulation material has low internal stress, good flexibility, and excellent resistance to cold and hot aging. Wherein, the silicone polymer segments have good flexibility and low internal stress; Benzoxazine/epoxy resin has the characteristic of strong water vapor barrier properties; and the combination of epoxy resin and benzoxazine can lower the curing temperature of benzoxazine. After opening the ring, benzoxazine acts as a curing agent participating in the curing crosslinking of epoxy groups, improving the crosslinking density of the cured epoxy resin in the system and further enhancing its gas barrier performance; SMB and SME are used as organic silicon polymer modified benzoxazine and epoxy precursor polymers, respectively. On one hand, they can improve the compatibility between low polarity organic silicon polymers and high polarity benzoxazine/epoxy resin systems. On the other hand, SMB ring-opening intermediates are curing agents of the epoxy ring opening reaction, which can promote the degree of reaction crosslinking and increase the crosslinking density of the system, thereby further reducing gas permeability. Under the synergistic coordination of various components, the obtained hybrid encapsulation material exhibits excellent gas barrier properties and good flexibility.

In addition, the mechanical strength of thermosetting resins is generally very high after complete curing, and it is difficult to rework if abnormalities are found after encapsulation and curing. However, the hybrid encapsulation material prepared by the present disclosure adopts segmented curing. The first step is to cure the organic silicon chain segment at room temperature and in air (at this time, the mechanical strength is low). If there are problems, they can be reworked and corrected in a timely manner. After confirming the correction, the temperature can be raised to 100° C. to 150° C. At this time, the epoxy and oxazine rings can continue to open the ring for thermal curing and crosslinking polymerization, further improving the mechanical strength of the colloid. This step-by-step dual-cured method can solve the difficult problem of repairing during the encapsulation process.

In some embodiments, the organosilicon polymer-benzoxazine-epoxy resin hybrid encapsulation material is prepared from the following components in parts by weight:

| | | |
|---|---|---|
| organosilicon-modified benzoxazine (SMB) | 30 to 60 | parts |
| organosilicon-modified epoxy resin (SME) | 50 to 90 | parts |
| bisphenol A benzoxazine resin | 10 to 20 | parts |
| aliphatic epoxy resin | 20 to 50 | parts |
| organosilicon polymer | 90 to 100 | parts |
| a catalyst | 0.001 to 0.5 | part |
| a crosslinking agent | 1 to 3 | parts |
| a powder filler | 25 to 50 | parts |

In some embodiments, the organosilicon polymer-benzoxazine-epoxy resin hybrid encapsulation material is prepared from the following components in parts by weight:

| | | |
|---|---|---|
| organosilicon-modified benzoxazine (SMB) | 45 to 55 | parts |
| organosilicon-modified epoxy resin (SME) | 75 to 85 | parts |
| bisphenol A benzoxazine resin | 10 to 15 | parts |
| aliphatic epoxy resin | 20 to 25 | parts |
| organosilicon polymer | 90 to 100 | parts |
| a catalyst | 0.001 to 0.5 | part |
| a crosslinking agent | 1 to 3 | parts |
| a powder filler | 25 to 50 | parts |

In some embodiments, the hydrogen content of the double-end hydrogen-containing silicone oil is 0.2 mmol/g to 0.6 mmol/g.

In some embodiments, the hydrogen content of the double-end hydrogen-containing silicone oil is 0.3 mmol/g to 0.5 mmol/g.

In some embodiments, the platinum catalyst is Castell platinum catalyst.

In some embodiments, the molar ratio of BZ compound, vinyltrimethoxysilane, and double-end hydrogen-containing silicone oil is 0.9 to 1.1:0.9 to 1.1:1.

In some embodiments, the molar ratio of allyl glycidyl ether, vinyltrimethoxysilane, and double-end hydrogen-containing silicone oil is 0.9 to 1.1:0.9 to 1.1:1.

In some embodiments, the organosilicon-modified benzoxazine contains polymers with the following structures:

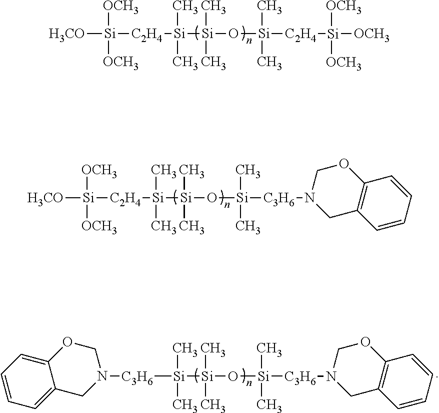

In some embodiments, the organosilicon-modified epoxy resin contains polymers with the following structures:

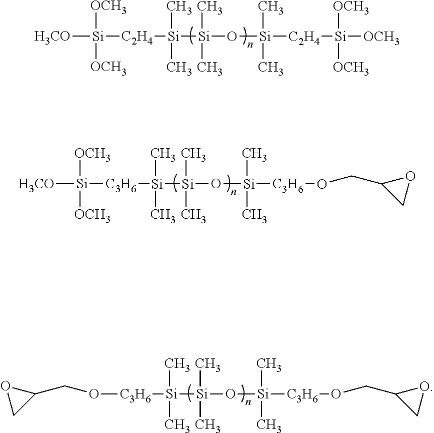

In some embodiments, the preparation method of the organosilicon-modified benzoxazine comprises the following steps: dissolving the BZ compound and vinyltrimethoxysilane in a solvent (such as toluene), adding the platinum catalyst, stirring evenly, adding the double-end hydrogen-containing silicone oil under the protection of nitrogen or inert gas, and then reacting for 4 h to 8 h at 20° C. to 60° C., removing the solvent to obtain the organosilicon-modified benzoxazine.

In some embodiments, the preparation method of the BZ compound comprises the following steps: dissolving phenol, allylamine, and polyformaldehyde in xylene, and reacting at 45° C. to 75° C. for 2 h to 4 h to obtain the BZ compound.

In some embodiments, the preparation method of the organosilicon-modified epoxy resin comprises the following steps: dissolving the allyl glycidyl ether, vinyltrimethoxysilane, and double-end hydrogen-containing silicone oil in a solvent (such as xylene), adding the platinum catalyst, stirring evenly, and reacting at 20° C. to 40° C. for 2 h to 6 h under nitrogen or inert gas protection, removing the solvent to obtain the organosilicon-modified epoxy resin.

In some embodiments, the structural formula of the bisphenol A benzoxazine resin is as follows:

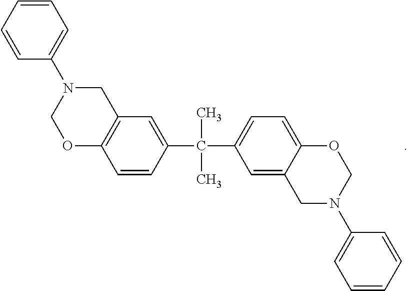 [SMILES: CC(C)(c1ccc2c(c1)CN(c1ccccc1)CO2)c1ccc2c(c1)CN(c1ccccc1)CO2]

In some embodiments, the aliphatic epoxy resin is 3,4-epoxycyclohexylmethyl 3′,4′-epoxycyclohexanecarboxylate.

In some embodiments, the organosilicon polymer is hydroxyl terminated polydimethylsiloxane and/or trimethoxy terminated polydimethylsiloxane.

In some embodiments, The viscosity of the hydroxyl terminated polydimethylsiloxane is 4000 mPa·s to 6000 mPa·s; the viscosity of the trimethoxy terminated polydimethylsiloxane is 4000 mPa·s to 6000 mPa. s.

In some embodiments, the catalyst is either an organic tin catalyst (such as dibutyltin dilaurate, etc.) or an organic titanium catalyst (such as isobutyl titanate, etc.).

In some embodiments, the powder filler is selected from at least one of gas-phase white carbon black, silicon micro powder, active nano-calcium carbonate, aluminum hydroxide, titanium dioxide, and iron oxide.

In some embodiments, the crosslinking agent is selected from at least one of methyltrimethoxysilane, methyltriethoxysilane, vinyltrimethoxysilane, methyltris(methylethylketoximino) silane, and vinyltris(methylethylketoximino) silane.

The organosilicon polymer-benzoxazine-epoxy resin hybrid encapsulation material of the present disclosure can be prepared as a bi-component hybrid encapsulation adhesive by conventional methods, or as a single-component encapsulation adhesive.

In one embodiment of the present disclosure, the component A in the bi-component hybrid encapsulation adhesive is composed of a mixture of organosilicon modified benzoxazine, organosilicon modified epoxy resin, bisphenol A benzoxazine resin, aliphatic epoxy resin, and crosslinking agent; component B is composed of a mixture of the organosilicon polymer, powder filler, and catalyst. When using, component A and component B are mixed evenly, then cured at room temperature (25±3° C./60±10% RH) for 6 h to 28 h, and then heat up to 100° C. to 150° C. and cured for 2 h to 5 h.

In one embodiment of the present disclosure, the raw materials for preparation of the single-component hybrid encapsulation adhesive further include 5 to 10 parts of silazane.

In one embodiment of the present disclosure, the preparation method for the single-component hybrid encapsulation adhesive includes following steps: adding the organosilicon polymer and a powder filler into a kneading machine, and then adding silazane for modification and refining to obtain a liquid base material;
transferring the liquid base material into a planetary machine, and then sequentially adding the organosilicon modified benzoxazine, organosilicon modified epoxy resin, bisphenol A benzoxazine resin, and aliphatic epoxy resin; heating up to 80° C. to 120° C., mixing evenly, cooling, and then adding a crosslinking agent and a catalyst in an anhydrous environment to obtain a single-component hybrid encapsulation adhesive. When useing, the obtained single-component hybrid encapsulation adhesive was cured at room temperature (25±3° C./60±10% RH) for 6 h to 28 h, then heated up to 100° C. to 150° C. and cured for 2 h to 5 h.

In some embodiments, the modified refining comprises the following steps: reacting for 2 h to 4 h at a temperature below 90° C. (e.g. 75° C. to 85° C.), evacuating to a vacuum degree of −0.075 MPa to −0.085 MPa, heating to 130° C. to 150° C., removing small molecules, adjusting the vacuum degree to −0.090 MPa to −0.095 MPa, and continuing the reaction for 1 h to 3 h.

The viscosity in the present disclosure refers to the viscosity tested at 25° C.

The room temperature in the present disclosure refers to the indoor temperature of 20° C. to 35° C.

The aliphatic epoxy resin used in the following embodiments is 3,4-epoxycyclohexylmethyl 3′,4′-epoxycyclohexanecarboxylate.

The structural formula of the bisphenol A benzoxazine resin used in the following embodiments is as follows:

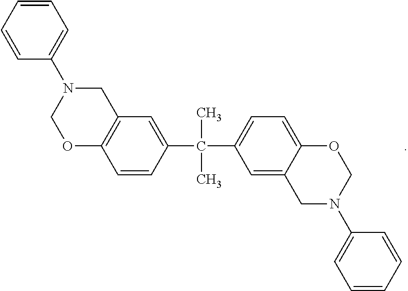 [SMILES: CC(C)(c1ccc2c(c1)CN(c1ccccc1)CO2)c1ccc2c(c1)CN(c1ccccc1)CO2]

In the following embodiments, the method for preparation of SMB is as follows:
Step 1: dissolving phenol, allylamine, and polyformaldehyde (molar ratio of 1:2:1) in xylene and reacting at 60° C. for 3 h to prepare a pale yellow BZ compound solution in xylene.

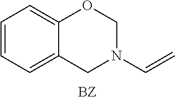

Structural characterization by FTIR: 1643 cm⁻¹ is the stretching vibration peak of the carbon-carbon double bond on the allyl group, 3081 cm⁻¹ and 3012 cm⁻¹ are the asymmetric stretching vibration peaks of carbon hydrogen of the carbon-carbon double bond on the allyl group. 849 cm⁻¹ and 992 cm⁻¹ are the out-of-plane bending vibration peaks of the C—H bond on the allyl group. 1481 cm⁻¹ is the asymmetric stretching peak of the Ar—O—C ether bond, and 922 cm⁻¹ is the characteristic peak of the oxazine ring.
Step 2: dissolving an equimolar amount of vinyltrimethoxysilane with BZ in a toluene solution of BZ compound, adding 10 ppm Castell platinum catalyst (based on the mass of platinum), stirring evenly, adding an equimolar amount of commercially available double-ended hydrogen containing silicone oil (Andsil CE100, hydrogen content 0.4 mmol/g) under N₂ protection, and then reacting at room temperature for 6 h. Vacuum distillation to remove solvent and obtain light yellow viscous liquid SMB; the reaction equation is as follows:

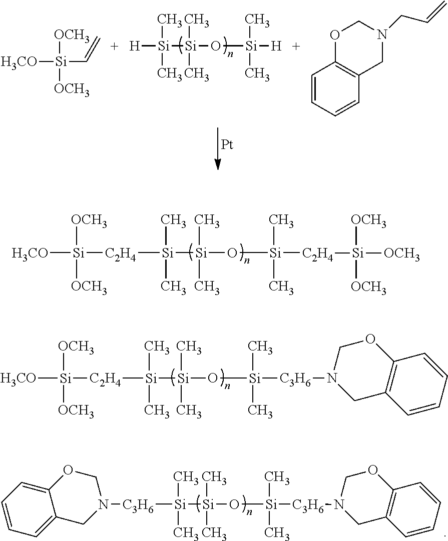

In the following embodiments, the method for preparation of SME is as follows:

Dissolving equimolar amounts of allyl glycidyl ether, vinyltrimethoxysilane, and double-end hydrogen-containing silicone oil (with a hydrogen content of 0.4 mmol/g) in xylene solvent, adding 5 ppm Castell platinum catalyst (based on the mass of platinum), stirring evenly, reacting at room temperature under N₂ protection for 4 h, and then vacuum distillation to remove solvent to obtain colorless transparent viscous liquid SME. The reaction equation is as follows:

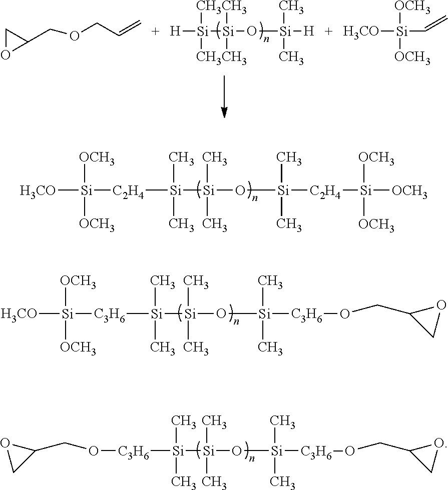

The following are specific implementation embodiments.

### Embodiment 1

This embodiment provides an organosilicon polymer-benzoxazine-epoxy resin hybrid encapsulation material (HPMI), being prepared from the following components in parts by weight:

| | | |
|---|---|---|
| organosilicon-modified benzoxazine (SMB): | 30 | parts |
| organosilicon-modified epoxy resin (SME): | 50 | parts |
| bisphenol A benzoxazine resin: | 20 | parts |
| aliphatic epoxy resin: | 50 | parts |
| 5000 mPa · s hydroxyl terminated polydimethylsiloxane: | 100 | parts |
| dibutyltin dilaurate: | 0.001 | part |
| active nano calcium carbonate with particle size of 200 nm: | 50 | parts |
| methyltrimethoxysilane: | 2 | parts, |

HPM1 was an A/B bi-component hybrid encapsulation adhesive, wherein component A was a mixture consisting of SMB, SME, bisphenol A benzoxazine resin, aliphatic epoxy resin, and methyltrimethoxysilane; component B was a mixture consisting of hydroxyl-terminated polydimethylsiloxane, active nano calcium carbonate, and organotin catalyst.

Before used, component A and component B were mixed evenly, then cured at room temperature (25±3° C./60±10% RH) for 6 h (2 mm of thickness), and then heated up to 135° C. for 4 h. The cured product was marked as PHPM1.

### Embodiment 2

This embodiment provides an organosilicon polymer-benzoxazine-epoxy resin hybrid encapsulation material (HPM2), being prepared from the following components in parts by weight:

| | | |
|---|---|---|
| organosilicon-modified benzoxazine (SMB): | 50 | parts |
| organosilicon-modified epoxy resin (SME): | 80 | parts |
| bisphenol A benzoxazine resin: | 10 | parts |
| aliphatic epoxy resin: | 20 | parts |
| 5000 mPa · s trimethoxy | 100 | parts |
| terminated polydimethylsiloxane: | | |
| methyl trimethoxysilane: | 2 | parts; |
| isobutyl titanate: | 0.5 | part; |
| gas-phase white carbon black (A200): | 30 | parts; |
| hexamethyldisilazane: | 6 | parts. |

The HPM2 in this embodiment was a single-component hybrid encapsulation adhesive, and the preparation method was as follows:

Adding trimethoxy terminated polydimethylsiloxane and gas-phase white carbon black into a kneading machine, then adding hexamethyldisilazane and kneading at 80° C. for 3 h. Evacuating to a vacuum degree of −0.080 MPa and heating up to 140° C. to remove small molecules. Adjusting the vacuum degree to −0.090 MPa and continuing the reaction for 2 h before cooling to room temperature to obtain a liquid base material.

Transferring the obtained liquid base material into a planetary machine, and then adding SMB, SME, bisphenol A benzoxazine resin, and aliphatic epoxy resin in sequence. Heating up to 100° C., mixing evenly, cooling to room temperature, and then adding methyltrimethoxysilane and isobutyl titanate in an anhydrous environment to form a single-component flow type hybrid encapsulation adhesive HPM2.

When used, the hybrid encapsulation adhesive HPM2 was cured at room temperature (25±3° C./60±10% RH) for 24 h (2 mm of thickness). After the colloid was completely cured, it was heated up to 140° C. and cured for 3 hours. The cured product was marked as PHPM2.

### Comparative Embodiment 1

The difference between this comparative embodiment and embodiment 2 is that SMB and SME were not added.

This comparative embodiment provides an organosilicon polymer-benzoxazine-epoxy resin hybrid encapsulation material (HPM3), being prepared from the following components in parts by weight:

| | | |
|---|---|---|
| bisphenol A benzoxazine resin: | 60 | parts |
| aliphatic epoxy resin: | 100 | parts |
| 5000 mPa · s trimethoxy terminated polydimethylsiloxane: | 100 | parts |
| methyl trimethoxysilane: | 2 | parts; |
| isobutyl titanate: | 0.5 | part; |
| gas-phase white carbon black (A200): | 30 | parts; |
| hexamethyldisilazane: | 6 | parts. |

The HPM3 in this embodiment was a single-component hybrid encapsulation adhesive, and the preparation method was as follows:

Adding trimethoxy terminated polydimethylsiloxane and gas-phase white carbon black into a kneading machine, then adding hexamethyldisilazane and kneading at 80° C. for 3 h. Evacuating to a vacuum degree of −0.080 MPa and heating up to 140° C. to remove small molecules. Adjusting the vacuum degree to −0.090 MPa and continuing the reaction for 2 h before cooling to room temperature to obtain a liquid base material.

Transferring the obtained liquid base material into a planetary machine, and then adding bisphenol A benzoxazine resin, and aliphatic epoxy resin in sequence. Heating up to 100° C., mixing evenly, cooling to room temperature, and then adding methyltrimethoxysilane and isobutyl titanate in an anhydrous environment to form a single-component flow type hybrid encapsulation adhesive HPM3.

When used, the hybrid encapsulation adhesive HPM3 was cured at room temperature (25±3° C./60±10% RH) for 24 h (2 mm of thickness). After completely cured, it was heated up to 140° C. and cured for 3 h. The cured product was marked as PHPM3. Phenomenon: during the natural curing process, the phase separation is serious, the compatibility is poor, and large local stratification is formed.

### Comparative Embodiment 2

The difference between this comparative embodiment and embodiment 2 is that SMB was not added.

This comparative embodiment provides an organosilicon polymer-benzoxazine-epoxy resin hybrid encapsulation material (HPM4), being prepared from the following components in parts by weight:

| | | |
|---|---|---|
| organosilicon-modified epoxy resin (SME): | 80 | parts |
| bisphenol A benzoxazine resin: | 60 | parts |
| aliphatic epoxy resin: | 20 | parts |
| 5000 mPa · s trimethoxy terminated polydimethylsiloxane: | 100 | parts |
| methyl trimethoxysilane: | 2 | parts; |
| isobutyl titanate: | 0.5 | part; |
| gas-phase white carbon black (A200): | 30 | parts; |
| hexamethyldisilazane: | 6 | parts. |

The HPM4 in this embodiment was a single-component hybrid encapsulation adhesive, and the preparation method was as follows:

Adding trimethoxy terminated polydimethylsiloxane and gas-phase white carbon black into a kneading machine, then adding hexamethyldisilazane and kneading at 80° C. for 3 h. Evacuating to a vacuum degree of −0.080 MPa and heating up to 140° C. to remove small molecules. Adjusting the vacuum degree to −0.090 MPa and continuing the reaction for 2 h before cooling to room temperature to obtain a liquid base material.

Transferring the obtained liquid base material into a planetary machine, and then adding SME, bisphenol A benzoxazine resin, and aliphatic epoxy resin in sequence. Heating up to 100° C., mixing evenly, cooling to room temperature, and then adding methyltrimethoxysilane and isobutyl titanate in an anhydrous environment to form a single-component flow type hybrid encapsulation adhesive HPM4.

When used, the hybrid encapsulation adhesive HPM4 was cured at room temperature (25±3° C./60±10% RH) for 24 h (2 mm of thickness). After completely cured, it was heated up to 140° C. and cured for 3 h. The cured product was marked as PHPM4, with phase separation in local areas.

### Comparative Embodiment 3

The difference between this comparative embodiment and embodiment 2 is that SME was not added.

This comparative embodiment provides an organosilicon polymer-benzoxazine-epoxy resin hybrid encapsulation material (HPM5), being prepared from the following components in parts by weight:

| | | |
|---|---|---|
| organosilicon-modified benzoxazine (SMB): | 50 | parts |
| bisphenol A benzoxazine resin: | 10 | parts |
| aliphatic epoxy resin: | 100 | parts |
| 5000 mPa · s trimethoxy terminated polydimethylsiloxane: | 100 | parts |
| methyl trimethoxysilane: | 2 | parts; |
| isobutyl titanate: | 0.5 | part; |
| gas-phase white carbon black (A200): | 30 | parts; |
| hexamethyldisilazane: | 6 | parts. |

The HPM5 in this embodiment was a single-component hybrid encapsulation adhesive, and the preparation method was as follows:

Adding trimethoxy terminated polydimethylsiloxane and gas-phase white carbon black into a kneading machine, then adding hexamethyldisilazane and kneading at 80° C. for 3 h. Evacuating to a vacuum degree of −0.080 MPa and heating up to 140° C. to remove small molecules. Adjusting the vacuum degree to −0.090 MPa and continuing the reaction for 2 h before cooling to room temperature to obtain a liquid base material.

Transferring the obtained liquid base material into a planetary machine, and then adding SMB, bisphenol A benzoxazine resin, and aliphatic epoxy resin in sequence. Heating up to 100° C., mixing evenly, cooling to room temperature, and then adding methyltrimethoxysilane and isobutyl titanate in an anhydrous environment to form a single-component flow type hybrid encapsulation adhesive HPM5.

When used, the hybrid encapsulation adhesive HPM5 was cured at room temperature (25±3° C./60±10% RH) for 24 h (2 mm of thickness). After completely cured, it was heated up to 140° C. and cured for 3 h. The cured product was marked as PHPM5, with phase separation in local areas.

### Comparative Embodiment 4

The difference between this comparative embodiment and embodiment 1 is that hydroxyl terminated polydimethylsiloxane was not added.

This comparative embodiment provides an organosilicon polymer-benzoxazine-epoxy resin hybrid encapsulation material (HPM6), being prepared from the following components in parts by weight:

| | | |
|---|---|---|
| organosilicon-modified benzoxazine (SMB): | 30 | parts |
| organosilicon-modified epoxy resin (SME): | 50 | parts |
| bisphenol A benzoxazine resin: | 60 | parts |
| aliphatic epoxy resin: | 110 | parts |
| methyltrimethoxysilane: | 2 | parts |
| active nano calcium carbonate with particle size of 200 nm: | 50 | parts |
| dibutyltin dilaurate: | 50 | ppm. |

HPM6 is an A/B bi-component hybrid encapsulation adhesive, wherein component A was a mixture of SMB, SME, bisphenol A benzoxazine resin, aliphatic epoxy resin, and methyltrimethoxysilane; component B was a mixture of active nano calcium carbonate, and organotin catalyst.

Before used, component A and component B were mixed evenly, then cured at room temperature (25±3° C./60±10% RH) for 6 h (2 mm of thickness), and then heated up to 135° C. for 4 h. The cured product was marked as PHPM6.

### Comparative Embodiment 5

The difference between this comparative embodiment and embodiment 1 is that bisphenol A benzoxazine resin and aliphatic epoxy resin were not added.

This comparative embodiment provides an organosilicon polymer-benzoxazine-epoxy resin hybrid encapsulation material (HPM7), being prepared from the following components in parts by weight:

| | | |
|---|---|---|
| organosilicon-modified benzoxazine (SMB): | 50 | parts |
| organosilicon-modified epoxy resin (SME): | 100 | parts |
| 5000 mPa · s hydroxyl terminated polydimethylsiloxane: | 100 | parts |
| active nano calcium carbonate with particle size of 200 nm: | 50 | parts |
| methyltrimethoxysilane: | 2 | parts |
| dibutyltin dilaurate: | 50 | ppm. |

HPM7 is an A/B bi-component hybrid encapsulation adhesive, wherein component A was a mixture of SMB, SME, and methyltrimethoxysilane; component B was a mixture of hydroxyl terminated polydimethylsiloxane, active nano calcium carbonate, and organotin catalyst.

Before used, component A and component B were mixed evenly, then cured at room temperature (25±3° C./60±10% RH) for 6 h (2 mm of thickness), and then heated up to 135° C. for 4 h. The cured product was marked as PHPM7.

### Embodiment 3: Performance Testing

The samples prepared in Embodiments 1-2 and Comparative Embodiments 1-5 were tested for key performance using relevant testing methods, as follows:

Viscosity: In the present disclosure, the immediate viscosity of the single-component hybrid encapsulation adhesive at the beginning of using and the bi-component hybrid encapsulation adhesive after uniform mixing were tested by using the method specified in GB/T 2794.

Tensile strength/elongation at break: according to the national standard GB/T 528-2009, the tensile strength and elongation at break was measured by making a type 1 spline sample.

Water vapor permeability: tested according to the European standard EN1279-4.

Cold and hot cycle aging: aging was carried out according to the 8.2 method in the national standard GB/T 36802-2018, and the mechanical strength and water vapor permeability of the cured material were repeatedly tested after aging.

The test data is shown in Table 1

TABLE 1
Results of performance test

| State | Performance | HPM1 | HPM2 | HPM3 | HPM4 | HPM5 | HPM6 | HPM7 |
|---|---|---|---|---|---|---|---|---|
| Uncured | Viscosity/mPa · s | 8500 | 28500 | 68500 | 38800 | 31600 | 5600 | 15800 |
| Before | Tensile | 3.68 | 4.72 | 1.56 | 2.21 | 2.68 | 7.38 | 2.85 |
| the aging | strength/MPa | | | | | | | |
| of the | Elongation at | 145 | 183 | 38 | 48 | 72 | 32 | 176 |
| solidified | break/% | | | | | | | |
| material | Water vapor | 4.82 | 3.69 | 18.9 | 11.3 | 9.16 | 1.67 | 8.56 |
| | permeability/ | | | | | | | |
| | (g/m2 · 24 h · | | | | | | | |
| | (2 mm) | | | | | | | |
| After | Tensile | 3.12 | 4.52 | 0.98 | 1.54 | 2.12 | 5.32 | 2.21 |
| the aging | strength/MPa | | | | | | | |
| of the | Elongation at | 166 | 212 | 25 | 39 | 88 | 25 | 125 |
| solidified | break/% | | | | | | | |
| material | Water vapor | 5.36 | 4.18 | 23.5 | 14.2 | 12.7 | 0.36 | 8.67 |
| | permeability/ | | | | | | | |
| | (g/m2 · 24 h · | | | | | | | |
| | (2 mm) | | | | | | | |

The organosilicon polymer-benzoxazine-epoxy resin hybrid encapsulation material of the present disclosure was formed into final cured material through moisture curing and heating-ring-opening curing, respectively. As shown in Table 1, the water vapor permeability of the hybrid encapsulation material obtained after curing was significantly reduced, and its toughness was greatly improved. At the same time, the material had excellent aging resistance.

The organic silicon modified benzoxazine SMB and organicsilicon modified epoxy resin SME prepared by the present disclosure effectively improved the compatibility between organic silicon polymer and benzoxazine/epoxy resin, and maximized the compatibility coupling between organic silicon polymer and benzoxazine/epoxy resin, which had a positive effect on improving the gas permeability of organic silicon and the flexibility of epoxy resin, thereby further improving the comprehensive performance of cured materials. SMB and SME played a bridging role in the compatible coupling of organosilicon polymers and epoxy/benzoxazine in the system, promoting compatibility. The lack of SMB and SME led to a decrease in the compatibility of the system, resulting in an overall deterioration of the material's overall performance.

The technical features of the embodiments above can be combined arbitrarily. To simplify the description, all possible combinations of the technical features of the embodiments above are not described. However, as long as there is no contradiction in the combination of these technical features, they should be considered to be within the scope of the specification.

The embodiments above merely express several implementations of the present disclosure. The descriptions of the embodiments are relatively specific and detailed, but may not therefore be construed as the limitation on the patent scope of the present disclosure. It should be noted that a person of ordinary skill in the art may further make several variations and improvements without departing from the concept of the present disclosure. These variations and improvements all fall within the protection scope of the present disclosure. Therefore, the patent protection scope of the present disclosure shall be defined by the appended claims.

What is claimed is:

1. An organosilicon polymer-benzoxazine-epoxy resin hybrid encapsulation material, being prepared from a raw material comprising the following components in parts by weight:
10 to 100 parts of an organosilicon-modified benzoxazine;
10 to 100 parts of an organosilicon-modified epoxy resin;
10 to 30 parts of a bisphenol A benzoxazine resin;
10 to 100 parts of an aliphatic epoxy resin;
10 to 150 parts of an organosilicon polymer;
0.0001 to 1 part of a catalyst;
0.5 to 10 parts of a crosslinking agent; and
10 to 100 parts of a powder filler;
wherein the organosilicon-modified benzoxazine is a mixture prepared by a hydrosilylation reaction of a BZ compound, vinyl trimethoxysilane, and a double-end hydrogen-containing silicone oil under a catalysis of a platinum catalyst;
wherein a structural formula of the BZ compound is as follows: 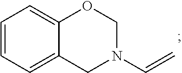
wherein the organosilicon-modified epoxy resin is a mixture prepared by a hydrosilylation reaction of an allyl glycidyl ether, vinyl trimethoxysilane, and the double-end hydrogen-containing silicone oil under the catalysis of the platinum catalyst.

2. The organosilicon polymer-benzoxazine-epoxy resin hybrid encapsulation material according to claim 1, wherein the organosilicon polymer-benzoxazine-epoxy resin hybrid encapsulation material is prepared from the raw material comprising the following components in parts by weight:
30 to 60 parts of the organosilicon-modified benzoxazine;
50 to 90 parts of the organosilicon-modified epoxy resin;
10 to 20 parts of the bisphenol A benzoxazine resin;
20 to 50 parts of the aliphatic epoxy resin;
90 to 100 parts of the organosilicon polymer;
0.001 to 0.5 part of the catalyst;
1 to 3 parts of the crosslinking agent; and
25 to 50 parts of the powder filler.

3. The organosilicon polymer-benzoxazine-epoxy resin hybrid encapsulation material according to claim 1, wherein the double-end hydrogen-containing silicone oil has a hydrogen content of 0.2 mmol/g to 0.6 mmol/g; and/or
the platinum catalyst is a Castell platinum catalyst; and/or
a molar ratio of the BZ compound, vinyl trimethoxysilane, and the double-end hydrogen-containing silicone oil is 0.9 to 1.1:0.9 to 1.1:1 in the hydrosilylation reaction for preparing the organosilicon-modified benzoxazine; and/or
a molar ratio of the allyl glycidyl ether, vinyl trimethoxysilane, and the double-end hydrogen-containing silicone oil is 0.9 to 1.1:0.9 to 1.1:1 in the hydrosilylation reaction for preparing the organosilicon-modified epoxy resin.

4. The organosilicon polymer-benzoxazine-epoxy resin hybrid encapsulation material according to claim 1, wherein the organosilicon-modified benzoxazine contains polymers with the following structures: 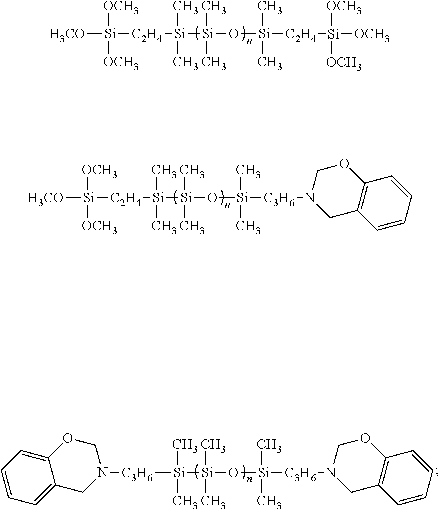
and/or,
the organosilicon-modified epoxy resin contains polymers with the following structures:

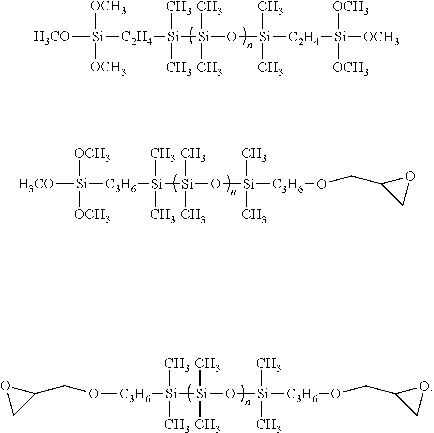

5. The organosilicon polymer-benzoxazine-epoxy resin hybrid encapsulation material according to claim 1, wherein a preparation method of the organosilicon-modified benzoxazine comprises the following steps: dissolving the BZ compound and vinyl trimethoxysilane in a solvent, adding the platinum catalyst to the solvent, stirring evenly, adding the double-end hydrogen-containing silicone oil to the solvent under a protection of nitrogen or inert gas, and then reacting for 4 h to 8 h at 20° C. to 60° C., removing the solvent to obtain the organosilicon-modified benzoxazine.

6. The organosilicon polymer-benzoxazine-epoxy resin hybrid encapsulation material according to claim 3, wherein a preparation method of the organosilicon-modified benzoxazine comprises the following steps: dissolving the BZ compound and vinyl trimethoxysilane in a solvent, adding the platinum catalyst to the solvent, stirring evenly, adding the double-end hydrogen-containing silicone oil to the solvent under a protection of nitrogen or inert gas, and then reacting for 4 h to 8 h at 20° C. to 60° C., removing the solvent to obtain the organosilicon-modified benzoxazine.

7. The organosilicon polymer-benzoxazine-epoxy resin hybrid encapsulation material according to claim 4, wherein a preparation method of the organosilicon-modified benzoxazine comprises the following steps: dissolving the BZ compound and vinyl trimethoxysilane in a solvent, adding the platinum catalyst to the solvent, stirring evenly, adding the double-end hydrogen-containing silicone oil to the solvent under a protection of nitrogen or inert gas, and then reacting for 4 h to 8 h at 20° C. to 60° C., removing the solvent to obtain the organosilicon-modified benzoxazine.

8. The organosilicon polymer-benzoxazine-epoxy resin hybrid encapsulation material according to claim 5, wherein a preparation method of the BZ compound comprises the following steps: dissolving phenol, allylamine, and polyformaldehyde in xylene, and reacting at 45° C. to 75° C. for 2 to 4 hours to obtain the BZ compound.

9. The organosilicon polymer-benzoxazine-epoxy resin hybrid encapsulation material according to claim 1, wherein a preparation method of the organosilicon-modified epoxy resin comprises the following steps: dissolving the allyl glycidyl ether, vinyl trimethoxysilane, and the double-end hydrogen-containing silicone oil in a solvent, adding the platinum catalyst to the solvent, stirring evenly, and reacting at 20° C. to 40° C. for 2 h to 6 h under a protection of nitrogen or inert gas, removing the solvent to obtain the organosilicon-modified epoxy resin.

10. The organosilicon polymer-benzoxazine-epoxy resin hybrid encapsulation material according to claim 3, wherein a preparation method of the organosilicon-modified epoxy resin comprises the following steps: dissolving the allyl glycidyl ether, vinyl trimethoxysilane, and the double-end hydrogen-containing silicone oil in a solvent, adding the platinum catalyst to the solvent, stirring evenly, and reacting at 20° C. to 40° C. for 2 h to 6 h under a protection of nitrogen or inert gas, removing the solvent to obtain the organosilicon-modified epoxy resin.

11. The organosilicon polymer-benzoxazine-epoxy resin hybrid encapsulation material according to claim 4, wherein a preparation method of the organosilicon-modified epoxy resin comprises the following steps: dissolving the allyl glycidyl ether, vinyl trimethoxysilane, and the double-end hydrogen-containing silicone oil in a solvent, adding the platinum catalyst to the solvent, stirring evenly, and reacting at 20° C. to 40° C. for 2 h to 6 h under a protection of nitrogen or inert gas, removing the solvent to obtain the organosilicon-modified epoxy resin.

12. The organosilicon polymer-benzoxazine-epoxy resin hybrid encapsulation material according to claim 1, wherein a structural formula of the bisphenol A benzoxazine resin is as follows: 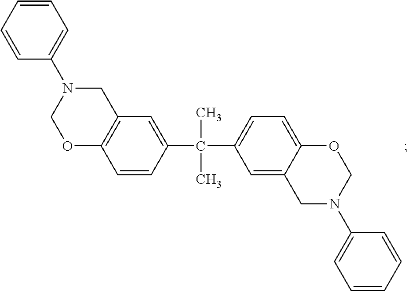 [SMILES: CC(C)(c1ccc2c(c1)CN(c1ccccc1)CO2)c1ccc2c(c1)CN(c1ccccc1)CO2]
and/or
the aliphatic epoxy resin is 3,4-epoxycyclohexylmethyl 3′,4′-epoxycyclohexanecarboxylate; and/or
the organosilicon polymer is hydroxyl terminated polydimethylsiloxane and/or trimethoxy terminated polydimethylsiloxane; and/or
the catalyst is either an organic tin catalyst or an organic titanium catalyst; and/or
the powder filler is selected from at least one of gas-phase white carbon black, silicon micro powder, active nano calcium carbonate, aluminum hydroxide, titanium dioxide, and iron oxide; and/or,
the crosslinking agent is selected from at least one of methyltrimethoxysilane, methyltriethoxysilane, vinyltrimethoxysilane, methyltris(methylethylketoximino) silane, and vinyltris(methylethylketoximino) silane.

13. The organosilicon polymer-benzoxazine-epoxy resin hybrid encapsulation material according to claim 2, wherein a structural formula of the bisphenol A benzoxazine resin is as follows: 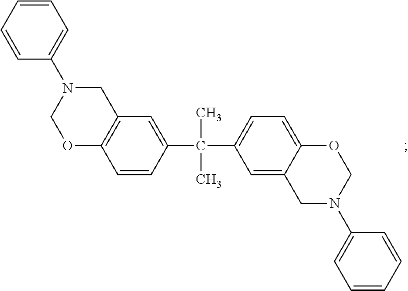 [SMILES: CC(C)(c1ccc2c(c1)CN(c1ccccc1)CO2)c1ccc2c(c1)CN(c1ccccc1)CO2]
and/or
the aliphatic epoxy resin is 3,4-epoxycyclohexylmethyl 3′,4′-epoxycyclohexanecarboxylate; and/or
the organosilicon polymer is hydroxyl terminated polydimethylsiloxane and/or trimethoxy terminated polydimethylsiloxane; and/or
the catalyst is either an organic tin catalyst or an organic titanium catalyst; and/or,
the powder filler is selected from at least one of gas-phase white carbon black, silicon micro powder, active nano calcium carbonate, aluminum hydroxide, titanium dioxide, and iron oxide; and/or
the crosslinking agent is selected from at least one of methyltrimethoxysilane, methyltriethoxysilane, vinyltrimethoxysilane, methyltris(methylethylketoximino) silane, and vinyltris(methylethylketoximino) silane.

14. The organosilicon polymer-benzoxazine-epoxy resin hybrid encapsulation material according to claim 3, wherein a structural formula of the bisphenol A benzoxazine resin is as follows: 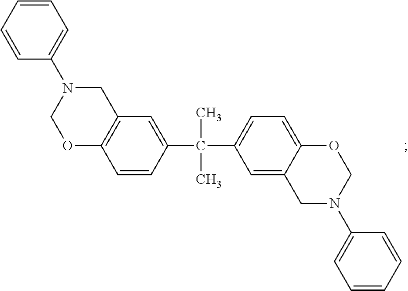 [SMILES: CC(C)(c1ccc2c(c1)CN(c1ccccc1)CO2)c1ccc2c(c1)CN(c1ccccc1)CO2]
and/or
the aliphatic epoxy resin is 3,4-epoxycyclohexylmethyl 3′,4′-epoxycyclohexanecarboxylate; and/or
the organosilicon polymer is hydroxyl terminated polydimethylsiloxane and/or trimethoxy terminated polydimethylsiloxane; and/or
the catalyst is either an organic tin catalyst or an organic titanium catalyst; and/or,
the powder filler is selected from at least one of gas-phase white carbon black, silicon micro powder, active nano calcium carbonate, aluminum hydroxide, titanium dioxide, and iron oxide; and/or
the crosslinking agent is selected from at least one of methyltrimethoxysilane, methyltriethoxysilane, vinyltrimethoxysilane, methyltris(methylethylketoximino)silane, and vinyltris(methylethylketoximino)silane.

15. The organosilicon polymer-benzoxazine-epoxy resin hybrid encapsulation material according to claim 4, wherein a structural formula of the bisphenol A benzoxazine resin is as follows: 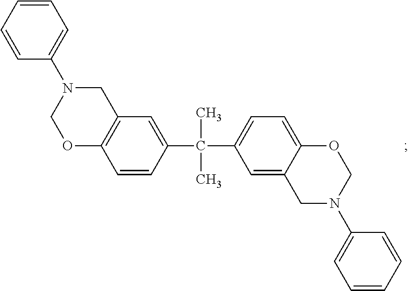 [SMILES: CC(C)(c1ccc2c(c1)CN(c1ccccc1)CO2)c1ccc2c(c1)CN(c1ccccc1)CO2]
and/or
the aliphatic epoxy resin is 3,4-epoxycyclohexylmethyl 3′,4′-epoxycyclohexanecarboxylate; and/or
the organosilicon polymer is hydroxyl terminated polydimethylsiloxane and/or trimethoxy terminated polydimethylsiloxane; and/or
the catalyst is either an organic tin catalyst or an organic titanium catalyst; and/or,
the powder filler is selected from at least one of gas-phase white carbon black, silicon micro powder, active nano calcium carbonate, aluminum hydroxide, titanium dioxide, and iron oxide; and/or
the crosslinking agent is selected from at least one of methyltrimethoxysilane, methyltriethoxysilane, vinyltrimethoxysilane, methyltris(methylethylketoximino)silane, and vinyltris(methylethylketoximino)silane.

16. The organosilicon polymer-benzoxazine-epoxy resin hybrid encapsulation material according to claim 1, wherein the organosilicon polymer-benzoxazine-epoxy resin hybrid encapsulation material is a bi-component hybrid encapsulation adhesive, a component A in the bi-component hybrid encapsulation adhesive is composed of a mixture of the organosilicon modified benzoxazine, the organosilicon modified epoxy resin, the bisphenol A benzoxazine resin, the aliphatic epoxy resin, and the crosslinking agent, and a component B in the bi-component hybrid encapsulation adhesive is composed of a mixture of the organosilicon polymer, the powder filler, and the catalyst; or
the organosilicon polymer-benzoxazine-epoxy resin hybrid encapsulation material is a single-component hybrid encapsulation adhesive, and the raw material for its preparation further includes 5 to 10 parts of silazane.

17. The organosilicon polymer-benzoxazine-epoxy resin hybrid encapsulation material according to claim 2, wherein the organosilicon polymer-benzoxazine-epoxy resin hybrid encapsulation material is a bi-component hybrid encapsulation adhesive, a component A in the bi-component hybrid encapsulation adhesive is composed of a mixture of the organosilicon modified benzoxazine, the organosilicon modified epoxy resin, the bisphenol A benzoxazine resin, the aliphatic epoxy resin, and the crosslinking agent, and a component B in the bi-component hybrid encapsulation adhesive is composed of a mixture of the organosilicon polymer, the powder filler, and the catalyst; or
the organosilicon polymer-benzoxazine-epoxy resin hybrid encapsulation material is a single-component hybrid encapsulation adhesive, and the raw material for its preparation further includes 5 to 10 parts of silazane.

18. The organosilicon polymer-benzoxazine-epoxy resin hybrid encapsulation material according to claim 3, wherein the organosilicon polymer-benzoxazine-epoxy resin hybrid encapsulation material is a bi-component hybrid encapsulation adhesive, a component A in the bi-component hybrid encapsulation adhesive is composed of a mixture of the organosilicon modified benzoxazine, the organosilicon modified epoxy resin, the bisphenol A benzoxazine resin, the aliphatic epoxy resin, and the crosslinking agent, and a component B in the bi-component hybrid encapsulation adhesive is composed of a mixture of the organosilicon polymer, the powder filler, and the catalyst; or
the organosilicon polymer-benzoxazine-epoxy resin hybrid encapsulation material is a single-component hybrid encapsulation adhesive, and the raw material for its preparation further includes 5 to 10 parts of silazane.

19. The organosilicon polymer-benzoxazine-epoxy resin hybrid encapsulation material according to claim 4, wherein the organosilicon polymer-benzoxazine-epoxy resin hybrid encapsulation material is a bi-component hybrid encapsulation adhesive, a component A in the bi-component hybrid encapsulation adhesive is composed of a mixture of the organosilicon modified benzoxazine, the organosilicon modified epoxy resin, the bisphenol A benzoxazine resin, the aliphatic epoxy resin, and the crosslinking agent, and a component B in the bi-component hybrid encapsulation adhesive is composed of a mixture of the organosilicon polymer, the powder filler, and the catalyst; or
the organosilicon polymer-benzoxazine-epoxy resin hybrid encapsulation material is a single-component hybrid encapsulation adhesive, and the raw material for its preparation further includes 5 to 10 parts of silazane.

20. A method for preparing the organosilicon polymer-benzoxazine-epoxy resin hybrid encapsulation material according to claim 1, wherein the organosilicon polymer-benzoxazine-epoxy resin hybrid encapsulation material is a single-component hybrid encapsulation adhesive, and the raw material for its preparation further comprises 5 to 10 parts of silazane; and its preparation method includes the following steps:
adding the organosilicon polymer and the powder filler into a kneading machine, and then adding silazane for modification and refining to obtain a liquid base material; and
transferring the liquid base material into a planetary machine, and then sequentially adding the organosilicon modified benzoxazine, the organosilicon modified epoxy resin, the bisphenol A benzoxazine resin, and the aliphatic epoxy resin; heating up to 80° C. to 120° C., mixing evenly, cooling, and then adding the crosslinking agent and the catalyst in an anhydrous environment to obtain the single-component hybrid encapsulation adhesive.
